(19) United States
(12) Patent Application Publication
(10) Pub. No.: US 2008/0278165 A1
(43) Pub. Date: Nov. 13, 2008

(54) Method and apparatus for reconstruction of an image in image space using basis functions (RIB) for partially parallel imaging

(76) Inventors: Yu Li, Gainesville, FL (US); Feng Huang, Gainesville, FL (US); G. Randy Duensing, Gainesville, FL (US)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/148,367

(22) Filed: Apr. 18, 2008

Related U.S. Application Data
(60) Provisional application No. 60/925,050, filed on Apr. 18, 2007.

(51) Int. Cl. G01R 33/48

(52) U.S. Cl. 324/312

(57) ABSTRACT

Embodiments of the invention pertain to a method and apparatus for image reconstruction for parallel Magnetic Resonance Imaging (MRI). In a specific embodiment, a method for image reconstruction in image space is provided. The method can suppress aliasing caused by undersampling when the number of sampling lines in k-space is reduced to increase the imaging speed. In an embodiment, suppressing aliasing from under-sampling can improve the quality of images reconstructed from the data acquired using a MRI coil array. In an embodiment, the method operates in image space and achieves a good resolution. In the reconstruction, the sum of square errors can be minimized within a region of interest, which can allow the image reconstruction to be optimized in a particular imaging region of interest by sacrificing the reconstruction of other regions. In a further embodiment, image reconstruction can be implemented region by region, allowing global optimization by spending a longer time in reconstruction.

### CROSS-REFERENCE TO RELATED APPLICATION

The present application claims the benefit of U.S. Application Ser. No. 60/925,050, filed Apr. 18, 2007, which is hereby incorporated by reference herein in its entirety, including any figures, tables, or drawings.

### BACKGROUND OF INVENTION

Parallel Magnetic Resonance Imaging (MRI) increases the imaging speed by reducing the number of sampling lines in k-space. The under-sampling introduces the aliasing in image space. Image reconstruction techniques for parallel MRI can be divided into two groups. One group of techniques operates in image space. As an example, in SENSifivity Encoding (SENSE), which operates in image space, the aliased image can be unwrapped by directly finding the inverse of the sensitivity matrix. The reconstruction is pixelwise and the calculation is fast. However, SENSE suffers from noise amplification because the sensitivity matrix is ill-conditioned in image space. The reconstruction quality is limited by the geometric factor. The other group of techniques operates in k-space and can be referred to as k-space operation methods. As examples, GeneRalized Autocalibrating Partially Parallel Acquisition (GRAPPA) and SiMultaneous Acquisition of Spatial Harmonics (SMASH) operate in k-space. Because k-space operation avoids the singularity problems associated with the sensitivity matrix, a least square method can be used to optimize the reconstruction based on auto-calibration signals (ACS). A disadvantage of this k-space operation method is the reconstruction is optimized for the entire image space and the local reconstruction may not be optimum.

### BRIEF SUMMARY

Embodiments of the invention pertain to a method and apparatus for image reconstruction for parallel Magnetic Resonance Imaging (MRI). In a specific embodiment, a method for image reconstruction in image space is provided. The method can suppress aliasing caused by undersampling when the number of sampling lines in k-space is reduced to increase the imaging speed. In an embodiment, suppressing aliasing from under-sampling can improve the quality of images reconstructed from the data acquired using a MRI coil array.

In an embodiment, the method operates in image space and achieves a good resolution. In the reconstruction, the sum of square errors can be minimized within a region of interest, which can allow the image reconstruction to be optimized in a particular imaging region of interest by sacrificing the reconstruction of other regions. In a further embodiment, image reconstruction can be implemented region by region, allowing global optimization by spending a longer time in reconstruction.

Various embodiments of the invention have advantages. In an embodiment, error in reconstruction for the data from different channels has little correlation. In another specific embodiment, image reconstruction is not g-factor limited. Image reconstruction can be optimized within a small region of interest, a larger region of interest, or over the entire image (global optimization), depending on the needs of the application. Embodiments of the invention enable the selection of basis functions to be coil dependent. The subject method of image reconstruction of parallel MRI can be implemented in software. Embodiments of the subject method are particularly useful in cardiac and prostate imaging.

### BRIEF DESCRIPTION OF DRAWINGS

FIG. 1 shows a high-resolution brain image acquired using a 4-channel head coil with an adequate sampling rate. This set of data was downsampled to generate the partially parallel imaging (PPI) data used for implementing an embodiment of the subject invention.

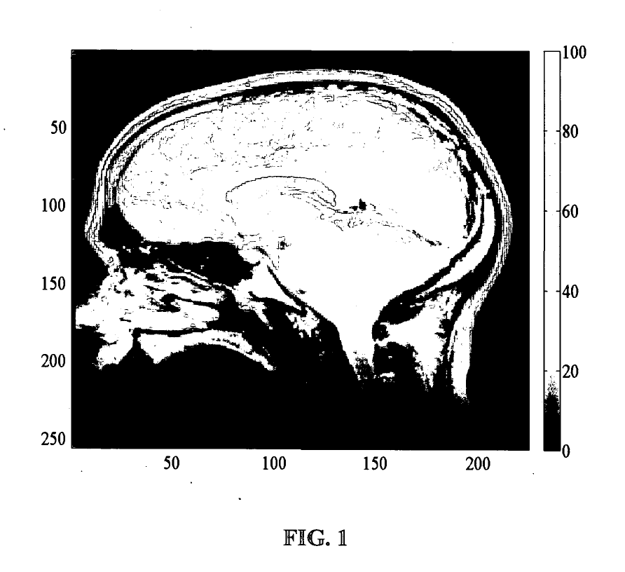

FIGS. 2A-2D show basis functions for an embodiment of reconstruction in image space using basis functions, where the basic functions are generated from the calibration data by Eigenmode analysis. A black region means that the corresponding Eigenmode is discarded in that region. It can be seen that only two low-order Eigenmodes remain in most regions. In high-order Eigenmodes, noise dominates the signal and, hence, the noise level in reconstruction can be reduced if only low-order Eigenmodes are used. FIG. 2A shows the first eigenmode; FIG. 2B shows the second eigenmode; FIG. 2C shows the third eigenmode; FIG. 2D shows the fourth eigemnode.

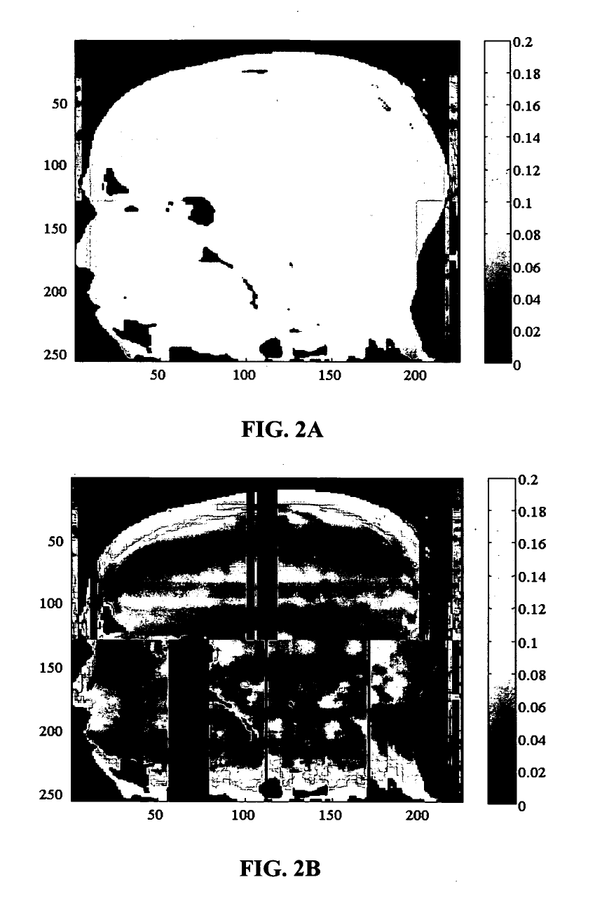

FIGS. 3A-3D show reconstruction results using SENSE and an embodiment of reconstruction in image space using basis functions, where the basic-functions are from a set of PPI data downsampled from the data used to produce the image of FIG. 1, with a reduction factor of 3. FIGS. 3A and 3B are the SENSE image and relative error image. Strong noise and artifacts, caused by inaccurate sensitivity maps and/or high g-factor, can be clearly seen in the relative error image. FIGS. 3C and 3D are the image reconstructed via an embodiment of the invention using basis functions and corresponding relative error image. It can be seen that the noise and artifacts are significantly reduced.

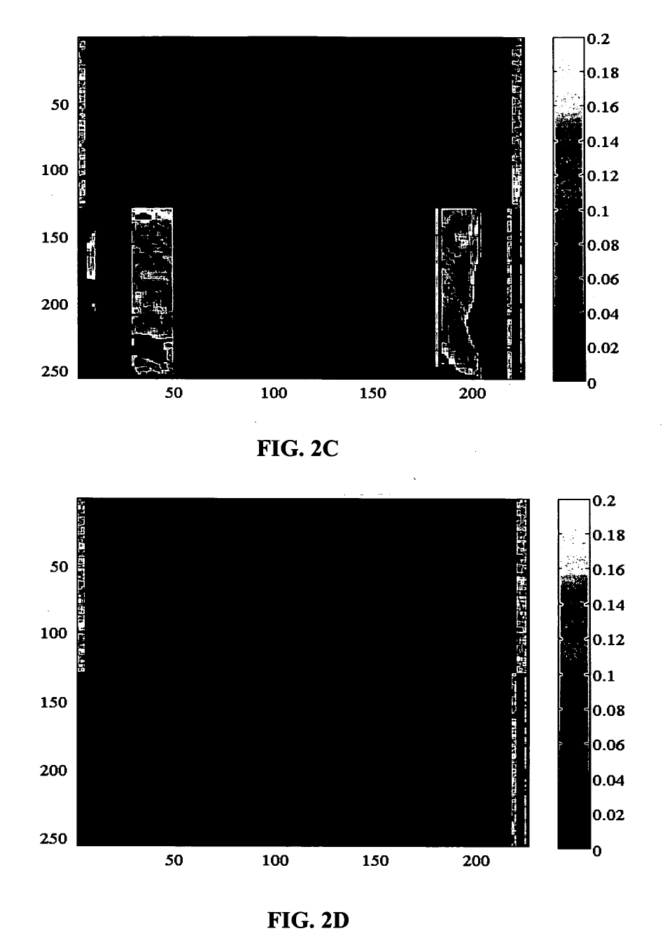

FIG. 4 shows a plurality of regions under construction (RUC's) where all the RUC's are connected to each other and cover the entire image space (FOV).

FIG. 5 shows a plurality of RUC's where the RUC's are not connected to each other and cover only a portion of image space (FOV).

FIG. 6 shows a plurality of RUC's where at least two of the RUC's overlap.

FIG. 7 shows some of the various shapes that the RUC's can have in accordance with embodiments of the subject invention.

FIG. 8 shows a single RUC that includes several regions that are not connected to each other.

### DETAILED DISCLOSURE

Embodiments of the invention pertain to a method and apparatus for image reconstruction for parallel Magnetic Resonance Imaging (MRI). In a specific embodiment, a method for image reconstruction in image space is provided. The method can suppress aliasing caused by undersampling when the number of sampling lines in k-space is reduced to increase the imaging speed. In an embodiment, suppressing aliasing from under-sampling can improve the quality of images reconstructed from the data acquired using a MRI coil array.

In an embodiment, the method operates in image space and achieves a good resolution. In the reconstruction, the sum of square errors can be minimized within a region of interest, which can allow the image reconstruction to be optimized in a particular imaging region of interest by sacrificing the reconstruction of other regions. In a further embodiment, image reconstruction can be implemented region by region, allowing global optimization by spending a longer time in reconstruction. The calculations for the reconstruction can be accomplished via any of a variety of means known to those skilled in the art, including, for example, computers, microprocessors, or other calculation apparatus.

Various embodiments of the invention have advantages. In a specific embodiment, error in reconstruction for the data from different channels has little correlation. In another specific embodiment, image reconstruction is not g-factor limited. Image reconstruction can be optimized within a small region of interest, a larger region of interest, or over the entire image (global optimization), depending on the needs of the application. Embodiments of the invention enable the selection of basis functions to be coil dependent. The subject method of image reconstruction of parallel MRI can be implemented in software. Embodiments of the subject method are particularly useful in cardiac and prostate imaging. The reconstructed images can be produced in a variety of media, including, but not limited to, computer screen, film, and print outs.

A mathematical representation of image reconstruction for parallel Magnetic Resonance Imaging (MRI) imaging in accordance with an embodiment of the invention is described below.

Let \vec{r} be a space vector in image space and Y(\vec{r}) be the reconstructed image. The image reconstruction from a set of partially parallel imaging (PPI) data acquired from an N-channel coil array can be mathematically represented in matrix form as shown in Ref. (16) by Eq. 1:

Y(\vec{r})=[H(\vec{r})][S(\vec{r})] (1)

where [H(\vec{r})]=[H₁(\vec{r}) H₂(\vec{r}) . . . H_{N}(\vec{r})] is the reconstruction vector, and

$$[ S ( \vec{r} ) ] = [ \begin{matrix}{S}_{1} ( \vec{r} ) \\ {S}_{2} ( \vec{r} ) \\ … \\ {S}_{N} ( \vec{r} )\end{matrix} ]$$

represents the N-channel wrapped images reconstructed from the PPI data by direct Fourier transform. Accordingly, referring to Equation (1), if we know [H(\vec{r})], then we can reconstruct the image Y(\vec{r}) from the N-channel wrapped images, [S(\vec{r})], reconstructed from the PPI data by direct Fourier transform. In a specific embodiment of reconstruction in image space using basic functions, it is assumed that the reconstruction vector can be represented by the following equation:

[H(\vec{r})]=[F(\vec{r})][A] (2)

where [F(\vec{r})]=[f₀(\vec{r})f₁(\vec{r}) . . . f_{M}(\vec{r})] is a set of M predefined basis functions, and

$$[ A ] = [ \begin{matrix}{a}_{10} & {a}_{20} & … & {a}_{N 0} \\ {a}_{11} & {a}_{21} & … & {a}_{N 1} \\ … & … & … & … \\ {a}_{1 M} & {a}_{2 M} & … & {a}_{NM}\end{matrix} ]$$

is an unknown coefficient matrix, which can be obtained by calibration with a set of alias-free low-resolution images. In an embodiment, the set of alias-free low-resolution images can be derived, for example, from either a pre-scan or extra ACS lines. Equation 2 allows pixel-by-pixel reconstruction if the coefficient matrix is calibrated for every pixel. More preferably, this calibration can be performed within a local region and all the pixels in this region can be reconstructed using a common coefficient matrix. This particular region can be referred to as a Region Under Consideration (RUC). The set of M predefined basis functions can be defined over the RUC.

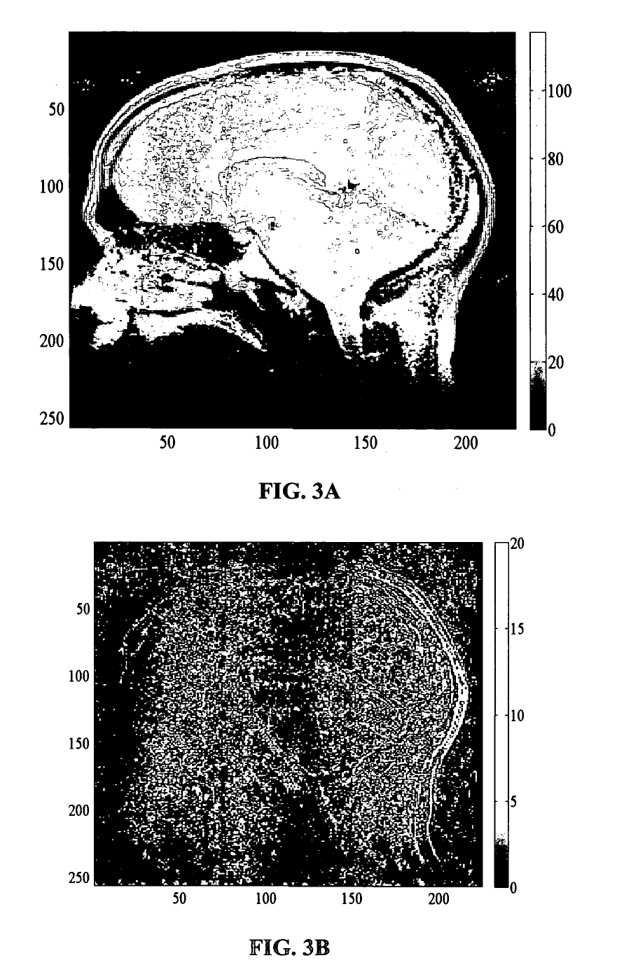

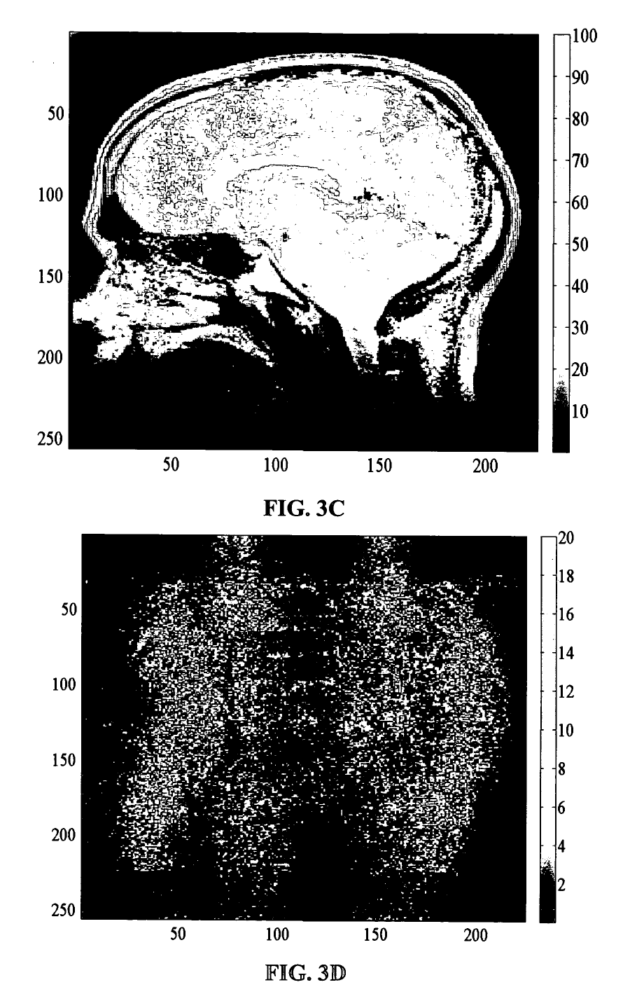

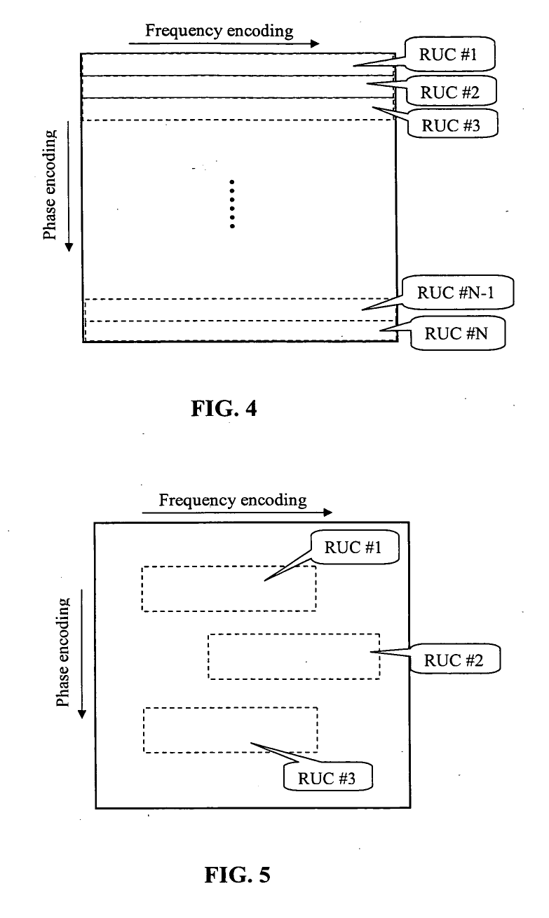

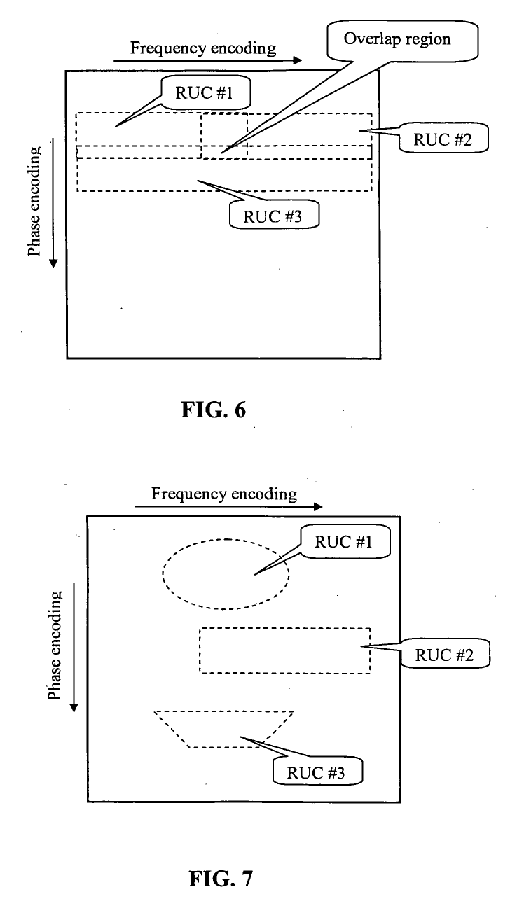

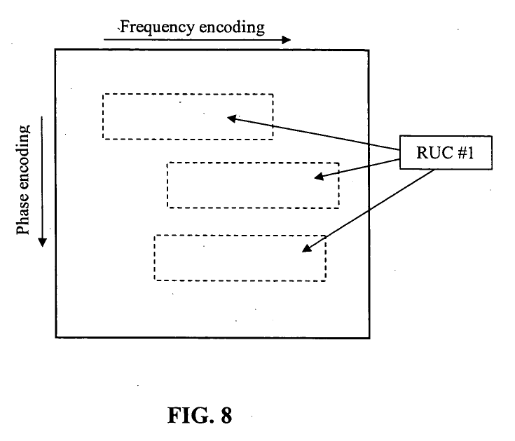

The RUC can be selected in a variety of ways that will be described in more detail with reference to FIGS. 4-8. One or more RUCs can be implemented in accordance with the subject invention. FIG. 4 shows a plurality of RUCs where the RUCs are connected to each other and cover the entire image space (FOV). Each RUC can be either a single image line or a few image lines in phase encoding direction. In other embodiments, the RUCs do not have to cover the entire image space. FIG. 5 shows a plurality of RUCs that are not connected to each other and cover only a portion of image space. Other embodiments can have some RUCs connected and others not connected. FIG. 6 shows overlapping RUCs, and FIG. 7 shows RUCs having a variety of shapes. Other embodiments can utilize RUCs with different shapes. FIG. 8 shows a single RUC that includes several regions that are not connected to each other.

The calibration of the coefficient matrix for a RUC can be implemented via a variety of techniques. In a specific embodiment, the calibration of the coefficient matrix for a RUC can be implemented by minimizing the sum of square error, as follows:

$${[ {A}^{*} ]}_{R U C} = {arg min}_{∀ [ A ]} \{ {\int }_{R U C} {( [ F ( \vec{r} ) ] [ A ] [ {S}_{x} ( \vec{r} ) ] - X ( \vec{r} ) )}^{2} d \vec{r} \} \qquad ( 3 a )$$

where [A*]_{RUC} is the optimal coefficient matrix for the RUC, X(\vec{r}) is the alias-free low-resolution image reconstructed from the sufficiently-sampled calibration data, and [Sₓ(\vec{r})] represents the N-channel wrapped images from the undersampled calibration data. X(\vec{r}) and [Sₓ(\vec{r})] can be obtained from, for example, prescan or ACS data. In a further embodiment, the calibration of the coefficient matrix for a RUC can be implemented by minimizing the sum of square error, as follows:

$${[ {A}^{*} ]}_{R U C} = {arg min}_{∀ A} {\int }_{R U C} \{ {α}_{R U C} [ F ( \vec{r} ) ] [ A ] {{Ψ [ A ]}^{H} [ F ( \vec{r} ) ]}^{H} + {\vert [ F ( \vec{r} ) ] [ A ] [ {S}_{X} ( \vec{r} ) ] - X ( \vec{r} ) \vert}^{2} \} d \vec{r} \qquad ( 3 b )$$

In alternative embodiments, the calibration of the coefficient matrix for an RUC can be implemented via other techniques. Referring to equations (3a) and (3b), these equations can be transformed into a matrix format and solved by, for example, the pseudo-inverse method. In other embodiments, equations (3a) and (3b) can be solved by other numerical methods. With A*, Eq. 1 and 2 can be applied for the reconstruction within an RUC. The reconstructed image, Y(\vec{r}), can be either the composite image or the image of one channel. If the reconstruction is implemented channel by channel, the single-channel images can then be combined using a conventional sum-of-squares reconstruction or any other optimal array combination. The image combining the single-channel images can be referred to as a composite image. Note that the shape of the RUC, as discussed above, can be arbitrary and, for example, can be a fraction of FOV, or the entire FOV can be divided into many RUC's. Hence, embodiments of the subject method offer the capability of reconstruction of an image within any region or regions in the image space.

To calibrate the coefficient matrix and calculate the reconstruction vector, a set of basis functions can be selected. In an embodiment, the basis functions can be found based on the a priori information about MRI coil sensitivity profiles and the sampling trajectory in parallel MRI data acquisition. In an embodiment, one or more of the assumptions listed below can be utilized in the determination of a set of basis functions:

1) the coil sensitivity profiles are smooth in image space;

2) if a coil array has a symmetric structure, its sensitivity profiles can be represented by a linear combination of several strong eigemmodes; and

3) if the sampling in k-space is uniform, the aliased image has a repeatable pattern.

The first assumption listed above is applicable in most, if not all, parallel imaging applications. The second and the third assumptions are useful in particular parallel imaging applications. Four examples are described below for determining a set of basis functions. For the convenience of representation, only two-dimensional Cartesian imaging is considered. The phase encoding is in x direction and the frequency encoding is in y direction. Additional embodiments of the invention can expand these two-dimensional examples into-three-dimensional applications and/or non-Cartesian imaging such as radial and spinal.

With respect to the calibration and reconstruction, the computation efficiency can be achieved when the image data within the RUC is used. Another simple way is to assign zeros to all the pixels outside of the RUC and use all the data over the image space to perform calibration and reconstruction. In this way, which can be referred to as zeropadding, the programming is easy, but the computation efficiency is low.

### EXAMPLE 1

### Head Imaging with Uniform Sampling Pattern

In a specific example, the coil sensitivity profiles of a head coil array are smooth and have a circular eigenmode structure. It is reasonable to assume that a set of basis functions including some low-order harmonics and some eigenmode patterns would be appropriate. Because the uniform sampling pattern in k-space can give a repeatable aliasing pattern in phased encoding direction, it is also reasonable to include some higher-order harmonics in the phase direction in the set of basis functions. Accordingly, in an embodiment, a set of basis functions for an eight-channel head coil can be:

$$\{ \begin{matrix}1 \\ exp ( \frac{j 2 π {n}_{x} x}{{FOV}_{x}} ) ; {n}_{x} = \pm 1 \\ exp ( \frac{j 2 π {n}_{y} y}{{FOV}_{y}} ) ; {n}_{y} = \pm 1 \\ exp ( j 2 π ( \frac{{n}_{x} x}{{FOV}_{x}} + \frac{{n}_{y} y}{{FOV}_{y}} ) ) ; {n}_{x} = \pm 2 ; {n}_{y} = 0 , \pm 1 \\ exp ( j ϕ ( x , y ) ) ; ϕ ( x , y ) = {tan}^{- 1} ( y / x )\end{matrix} \qquad ( 3 )$$

where FOVₓ and FOV_{y} are the field of view in x and y directions respectively. In Eq. (4), the first three lines are some low-order harmonics; the fourth line represents some high-order harmonics in x direction; and the last line is the eigenmode structure.

### EXAMPLE 2

### Planar Coil with Uniform Sampling Pattern

For some planar coils, such as cardiac coils, the eigenmode structure is not clear. There are many choices available for basic functions. In an embodiment, a set of polynomial basis functions can be used to model the reconstruction matrix:

$$\{ \begin{matrix}1 \\ {x}^{n} exp ( - \frac{{x}^{2}}{2} ) ; n = 1 , 2 , 3 \\ y exp ( - \frac{{y}^{2}}{2} )\end{matrix} \qquad ( 4 )$$

This set of basis functions includes some low-order polynomials to account for the smoothness of the coil sensitivity profiles, and several high-order polynomials in the x direction to account for the repeatable aliasing pattern.

### EXAMPLE 3

### Eigenmode Analysis on General Convolution Kernels

Because the reconstruction matrix is dependent only on the MRI coils and the sampling trajectory, it is possible to find a set of general basis functions related to a coil configuration based on one set of imaging data acquired via the coil configuration. In an embodiment, a full k-space data set can be acquired and used to determine a set of general basis functions for a MRI coil configuration. A convolution kernel of large size for image reconstruction can be resolved in k-space based on a particular sampling trajectory. This procedure is similar to that to find the convolution kernel using ACS lines in the GRAPPA method. The resolved convolution kernel can be transformed to image space. Those important eigenmodes of this set of kernel can be used as the basis functions for the image reconstruction from any image data acquired using the same coil. Excluding some eigenmodes creates a basis function set that differs from the convolution kernel.

### EXAMPLE 4

### Eigenmode Analysis on Calibration Images

By comparing an embodiment of the subject method for reconstruction in image space using basis functions for partially parallel imaging and SENSE, it is found that a solution to the basis functions in Eq. (1) can be the Eigenvectors of the sensitivity matrix. This provides a means to automatically generate the basis functions. Physically, the Eigenvectors of the sensitivity matrix correspond to the Eigenmodes of the RF coil array; hence, the Eigenvectors can be found by Eigenmode analysis on the sensitivity maps. Sensitivity maps can be calculated from the calibration images. More practically, the basis functions can be defined as the Eigenvectors obtained by applying Eigenmode analysis directly to the calibration images. Because the calibration of coefficient matrix in this method can compensate the difference of sensitivity maps and images, this set of basis functions can give the same reconstruction as that using sensitivity maps.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

### REFERENCES

1). King S. B. et al. Pro c. ISMRM, p. 712, 2003.
2). Prussmann, K. P. et. al., MRM 42: 952-962 (1999).

1. A method of reconstruction of an image from partially parallel magnetic resonance imaging (MRI) data, comprising:
a. receiving partially parallel MRI data for a full image, [S(\vec{r})], over a field of view;
b. determining [H(\vec{r})] for a subregion, wherein an image of the subregion of the field of view is represented as Y(\vec{r})=[H(\vec{r})][S(\vec{r})], where [H(\vec{r})]=[F(\vec{r})][A], where [F(\vec{r})] is a predetermined set of basis functions defined over the subregion and [A] is a coefficient matrix; and
c. reconstructing the image of the subregion, Y(\vec{r}), by Y(\vec{r})=[H(\vec{r})][S(\vec{r})].

2. The method according to claim 1, wherein [S(\vec{r})] is in image space.

3. The method according to claim 1, wherein [S(\vec{r})] is calculated from MRI data acquired in Cartesian k-space.

4. The method according to claim 1, wherein [S(\vec{r})] is calculated from MRI data acquired in radial k-space.

5. The method according to claim 1, wherein [S(\vec{r})] is calculated from MRI data acquired in spiral k-space.

6. The method according to claim 1, wherein the predetermined set of basis functions is a set of polynomial basis functions.

7. The method according to claim 1, further comprising:
determining A by minimizing the sum of square errors in the region of interest.

8. The method according to claim 1, further comprising:
receiving low resolution MRI data;
$${[ {A}^{*} ]}_{R U C} = {arg min}_{∀ [ A ]} \{ {\int }_{R U C} {( [ F ( \vec{r} ) ] [ A ] [ {S}_{x} ( \vec{r} ) ] - X ( \vec{r} ) )}^{2} d \vec{r} \}$$
determining A by
where X(\vec{r}) is a low resolution image produced from the low resolution MRI data, where Sₓ(\vec{r}) is a folded image generated from X(\vec{r}).

9. The method according to claim 1, further comprising:
receiving low resolution MRI data;
determining A by
$${[ {A}^{*} ]}_{R U C} = {arg min}_{∀ A} {\int }_{R U C} \{ {α}_{R U C} [ F ( \vec{r} ) ] [ A ] {{Ψ [ A ]}^{H} [ F ( \vec{r} ) ]}^{H} + {\vert [ F ( \vec{r} ) ] [ A ] [ {S}_{X} ( \vec{r} ) ] - X ( \vec{r} ) \vert}^{2} \} d \vec{r} ,$$
where X(\vec{r}) is a low resolution image produced from the low resolution MRI data, where Sₓ(\vec{r}) is a folded image generated from X(\vec{r}), where α_{RUC} is a parameter to balance the noise amplification and data fitting error, where v is the noise correlation matrix for an RF coil array used to collect the partially parallel MRI data.

10. The method according to claim 8, wherein the low resolution MRI data is from a prescan.

11. The method according to claim 8, wherein the low resolution MRI data is from ACS lines.

12. The method according to claim 1, wherein the subregion is smaller than the field of view.

13. The method according to claim 1, further comprising:
repeating c for each of at least one additional subregion.

14. The method according to claim 13, wherein one or more of the subregion and the at least one additional subregion overlap.

15. The method according to claim 1, wherein the subregion has an arbitrary shape.

16. The method according to claim 13, wherein the subregion and the at least one additional subregion together cover the entire field of view.

17. The method according to claim 13, wherein one or more of the subregion and the at least one additional subregion are connected.

18. The method according to claim 1, wherein the predetermined set of basis functions are defined based on a priori information about MRI coil sensitivity profiles for an RF coil array used to collect the partially parallel MRI data.

19. The method according to claim 18, wherein the a priori information is based on a k-space data set for the RF coil array.

20. The method according to claim 18, wherein the a priori information comprises the Eigenmode for the RF coil array.

21. The method according to claim 18, wherein the predetermined set of basis functions are defined assuming the coil sensitivity profiles are smooth in image space.

22. The method according to claim 1, wherein the received partially parallel MRI data is two-dimensional partially parallel MRI data and [H(\vec{r})], [F(\vec{r})], Y(\vec{r}), and [A] are two-dimensional.

23. The method according to claim 1, wherein the received partially parallel MRI data is three-dimensional partially parallel MRI data and [H(\vec{r})], [F(\vec{r})], Y(\vec{r}), and [A] are three-dimensional.

24. The method according to claim 1, further comprising:
producing the image of the subregion.

25. The method according to claim 1, wherein the image of the subregion, Y(\vec{r}), corresponds to a first channel of the partially parallel MRI data, [S(\vec{r})].

26. The method according to claim 1, wherein the image of the subregion, Y(\vec{r}), corresponds to at least two channels of the partially parallel MRI data, [S(\vec{r})].

27. The method according to claim 25, further comprising:
repeating b and c for at least one additional channel of the partially parallel MRI data, [S(\vec{r})].

28. The method according to claim 27, further comprising:
combining the image of the subregion corresponding to the first channel and the image of the subregion corresponding to the at least one additional channel into a composite image.

29. The method according to claim 1, wherein the image of the subregion, Y(\vec{r}), corresponds to all channels of the partially parallel MRI data, [S(\vec{r})].

30. An apparatus for reconstructing an image, comprising:
a means for receiving partially parallel MRI data for a full image, [S(\vec{r})], over a field of view;
a means for determining [H(\vec{r})] for a subregion of the field of view, where an image of the subregion of the field of view is represented as Y(\vec{r})=[H(\vec{r})][S(\vec{r})], where
[H(\vec{r})]=[F(\vec{r})][A], wherein [F(\vec{r})] is a predetermined set of basis functions defined over the subregion; and
a means for reconstructing the image of the subregion, Y(\vec{r}), by Y(\vec{r})=[H(\vec{r})][S(\vec{r})].

31. The method according to claim 30, further comprising:
a means for producing the image of the subregion.
